(19) United States
(12) Patent Application Publication
(10) Pub. No.: US 2026/0040713 A1
(43) Pub. Date: Feb. 5, 2026

(54) SEMICONDUCTOR DEVICE, IMAGE PROCESSING APPARATUS INCLUDING THE SAME, AND OPERATING METHOD OF IMAGE PROCESSING DEVICE

(71) Applicant: KOREA ADVANCED INSTITUTE OF SCIENCE AND TECHNOLOGY, Daejeon (KR)

(72) Inventors: Himchan CHO, Daejeon (KR); Kyung Min KIM, Daejeon (KR); Seongbeom YEON, Daejeon (KR); Min Gu LEE, Daejeon (KR); Geunyoung KIM, Daejeon (KR); Jaehwan LEE, Daejeon (KR); Seungwoo LEE, Daejeon (KR)

(73) Assignee: KOREA ADVANCED INSTITUTE OF SCIENCE AND TECHNOLOGY, Daejeon (KR)

(21) Appl. No.: 19/281,461

(22) Filed: Jul. 25, 2025

(30) Foreign Application Priority Data
Jul. 31, 2024 (KR) 10-2024-0101667

(51) Int. Cl. H10F 39/00; H04N 25/771; H04N 25/772; H10F 30/22; H10F 77/14

(52) U.S. Cl. CPC H10F 39/811; H04N 25/771; H04N 25/772; H10F 30/22; H10F 39/803; H10F 77/1433

(57) ABSTRACT

The present disclosure relates to a semiconductor device, an image processing apparatus, and a method for operating the image processing apparatus. The semiconductor device includes a first electrode layer, a charge storage layer, an active layer, a second electrode layer, and a photo-sensitive layer. The charge storage layer is disposed on the first electrode layer and the base substrate and stores charges injected by a gate voltage applied to the first electrode layer. The active layer is disposed on the charge storage layer and injects charges into the charge storage layer based on the gate voltage. The second electrode layer is in contact with a portion of the active layer to be electrically connected to the active layer. The photo-sensitive layer is disposed on the active layer and provides charge to the active layer based on an optical signal.

### CROSS-REFERENCE TO RELATED APPLICATIONS

This application claims priority to and benefits of Korean Patent Application No. 10-2024-0101667 under 35 U.S.C § 119, filed on Jul. 31, 2024, in the Korean Intellectual Property Office, the contents of which are incorporated herein in its entirety by reference.

### BACKGROUND

### 1. Technical Field

The present disclosure relates to a semiconductor device, an image processing apparatus including the same, and an operating method of the image processing apparatus. More particularly, the disclosure pertains to a semiconductor device capable of both optical sensing and data storage, an image processing apparatus including such a device, and a method for operating the image processing apparatus.

### 2. Description of the Related Art

With advancements in digital technology, society is entering a hyper-connected era where all things are digitally interconnected. Consequently, vast amounts of data are generated across many areas of daily life. This big data often comprises unstructured formats, such as text, images, audio, and video, and processing such data requires significant time and energy consumption. Therefore, there is a growing demand for more efficient data processing within shorter times and at lower power consumption.

Conventional data processing systems are structured such that sensing, storage, and computation are performed by separate components. This architecture necessitates a serial configuration of sensors, memory units, and computing devices for unstructured data processing, resulting in low integration density and large-scale hardware. Moreover, data transfer bottlenecks in such systems lead to increased power loss and prolonged processing times. Thus, structural innovation in hardware architecture is required to achieve more efficient data processing.

### SUMMARY

The present disclosure aims to address issues related to high power consumption and long processing times associated with unstructured data processing. Specifically, an object of the present disclosure is to provide a semiconductor device capable of both optical sensing and data storage, which can also be utilized in the data computation process, as well as to provide an image processing apparatus including the semiconductor device and a method for operating the image processing apparatus.

According to an embodiment of the present disclosure, a semiconductor device includes a base substrate, a first electrode layer, a charge storage layer, an active layer, a second electrode layer, and a photo-sensitive layer. The first electrode layer is disposed on the base substrate. The charge storage layer is disposed on the base substrate and the first electrode layer and is configured to store charges injected in response to a gate voltage applied to the first electrode layer. The active layer is disposed on the charge storage layer and is configured to inject charges into the charge storage layer based on the gate voltage. The second electrode layer is disposed to contact a portion of the active layer so as to be electrically connected to the active layer. The photo-sensitive layer is disposed on the active layer so as to at least partially overlap with the active layer and the charge storage layer, and is configured to provide charges to the active layer in response to an optical signal.

In one example, the photo-sensitive layer may include a quantum dot layer including a semiconductor material in the form of nanoparticles. For example, the quantum dot layer may include quantum dots having surface forming ligands, and the ligands may include a combination of heterogeneous inorganic materials. In one example, the quantum dot layer may include colloidal inorganic quantum dots, wherein ligands including organic and inorganic materials are formed on the surface thereof, and the colloidal inorganic quantum dots are dispersed by a dispersion solvent including water or an organic solvent.

In one example, the charge storage layer may include a blocking layer, a charge trapping layer, and a tunneling layer. The blocking layer may be disposed between the first electrode layer and the active layer and configured to block movement of charges injected from the active layer to the first electrode layer. The charge trapping layer may be disposed between the blocking layer and the active layer and configured to trap charges injected from the active layer. The tunneling layer may be disposed between the charge trapping layer and the active layer and configured to control the movement of charges between the charge trapping layer and the active layer depending on the gate voltage.

In one example, when the gate voltage applied to the first electrode layer is at a program voltage level that is higher than the voltage level of the second electrode layer, charges may be injected from the active layer into the charge storage layer. When the gate voltage is at the program voltage level and charges are provided from the photo-sensitive layer to the active layer based on an optical signal, the charges provided to the active layer may be injected into the charge storage layer.

In one example, when the gate voltage applied to the first electrode layer is at an erase voltage level that is lower than the voltage level of the second electrode layer, charges may be released from the charge storage layer to the active layer.

In one example, when the gate voltage applied to the first electrode layer is at a read voltage level that is lower than the program voltage level, charges may be provided from the photo-sensitive layer to the active layer based on an optical signal, and the charges may flow to the second electrode layer through the active layer.

In one example, the magnitude of current flowing through the active layer to the second electrode layer may depend on the intensity of the optical signal and the amount of charge trapped in the charge storage layer.

According to an embodiment of the present disclosure, an image processing apparatus includes a pixel array, a conversion circuit, and a driving circuit. The pixel array includes a plurality of pixels each having a semiconductor device configured to generate an analog electrical signal in response to an optical signal. The conversion circuit is configured to convert the analog signal into a digital signal. The driving circuit is configured to control voltages applied to the pixel array. The semiconductor device includes a photo-sensitive layer configured to convert an optical signal into an electrical signal, a charge storage layer configured to trap charges to adjust the magnitude of the electrical signal, and an active layer disposed between the photo-sensitive layer and the charge storage layer and configured to form a channel for transferring the analog signal to the conversion circuit based on a voltage applied by the driving circuit.

In one example, the image processing apparatus may further include gate lines, source lines, and drain lines. The gate lines are connected between the driving circuit and the pixel array and are configured to transmit a gate voltage from the driving circuit to the semiconductor device to control formation of the channel. The drain lines are connected between the driving circuit and the pixel array and are configured to transmit a drain voltage from the driving circuit to the semiconductor device to supply charges to the channel. The source lines are connected between the pixel array and the conversion circuit and are configured to transfer the analog signal to the conversion circuit.

In one example, the semiconductor device may further include a gate electrode, a source electrode, and a drain electrode. The gate electrode may be electrically connected to the gate line and disposed to face the active layer with the charge storage layer interposed therebetween. The source electrode may be electrically connected to the source line and disposed to be in contact with a first portion of the active layer on the charge storage layer and the active layer. The drain electrode may be electrically connected to the drain line and disposed to be in contact with a second portion of the active layer, different from the first portion, on the charge storage layer and the active layer.

In one example, the driving circuit may be configured to control the voltage level of the gate voltage to inject charges from the active layer into the charge storage layer or to release charges from the charge storage layer into the active layer.

In one example, the driving circuit may be configured to apply a drain voltage to a pixel connected to the drain line and to apply a gate voltage at a program voltage level that is higher than the drain voltage through the gate line connected to the pixel, thereby storing weight data in the pixel. In one example, the driving circuit may be configured to apply a gate voltage at a read voltage level that is lower than the program voltage level and a drain voltage to enable current flow through the channel, and the semiconductor device may output the analog signal to the conversion circuit based on the gate voltage at the read voltage level.

In one example, the analog signal may have the magnitude of current dependent on the amount of charge provided to the active layer by the optical signal and the amount of charge trapped in the charge storage layer.

According to an embodiment of the present disclosure, in a method for operating an image processing apparatus, the image processing apparatus includes a pixel array, which includes a semiconductor device configured to generate analog electrical signals based on optical signals, and a driving circuit, which is configured to control voltages applied to the pixel array. The method includes: applying, by the driving circuit, a gate voltage at a program voltage level to the semiconductor device to store weight data in a charge storage layer of the semiconductor device; detecting an image by providing charges to an active layer of the semiconductor device from a photo-sensitive layer of the semiconductor device in response to an optical signal; and performing image preprocessing by generating an analog signal based on the weight data and the charges provided to the active layer.

In one example, the storing of weight data may include applying, by the driving circuit, a gate voltage to a gate electrode of the semiconductor device facing the active layer with the charge storage layer interposed therebetween, and injecting charges present in the active layer into the charge storage layer based on the gate voltage.

In one example, the detecting of an image may include forming an electron-hole pair in the photo-sensitive layer in response to an external optical signal, and transferring electrons of the electron-hole pair from the photo-sensitive layer to the active layer. The magnitude of the analog signal may be determined based on the conductivity of the active layer, which is dependent on the weight data.

According to an embodiment of the present disclosure, the semiconductor device, the image processing apparatus including the same, and the method for operating the image processing apparatus may enable simultaneous optical sensing and data storage, thereby providing a structure capable of performing computation and learning autonomously using the sensed optical signals and the stored data.

### BRIEF DESCRIPTION OF THE DRAWINGS

These and/or other features will become apparent and more readily appreciated from the following description of the embodiments, taken in conjunction with the accompanying drawings.

FIG. 1 is a block diagram of an image processing apparatus according to an embodiment of the present disclosure.

FIG. 2 is a circuit diagram of the pixel array shown in FIG. 1.

FIG. 3 is a perspective view of the semiconductor device of FIGS. 1 and 2.

FIG. 4 illustrates an embodiment of the photo-sensitive layer shown in FIG. 3.

FIG. 5 is a graph illustrating the effect of introducing inorganic ligands to quantum dots applied in FIG. 4.

FIG. 6 is an energy band diagram of the semiconductor device of FIG. 3 in a state where no gate voltage is applied.

FIG. 7 is an energy band diagram of the semiconductor device of FIG. 3 during a program operation.

FIG. 8 is an energy band diagram of the semiconductor device of FIG. 3 during an erase operation.

FIG. 9 is a graph illustrating effects according to the program operation of FIG. 7 and the erase operation of FIG. 8.

FIG. 10 is an energy band diagram of the semiconductor device of FIG. 3 during a light-receiving operation.

FIG. 11 is an energy band diagram of the semiconductor device of FIG. 3 during light-receiving and program operations.

FIG. 12 is a flowchart of a method for operating the image processing apparatus according to an embodiment of the present disclosure.

### DETAILED DESCRIPTION

Hereinafter, certain embodiments of the present disclosure will be described in more detail with reference to the accompanying drawings. In the drawings, the proportions and dimensions of components may be exaggerated for clarity and ease of explanation.

Any expressions such as “comprise” or “include” are intended to specify the presence of features, integers, steps, operations, elements, components, or combinations thereof stated in the specification, and shall not be construed to preclude any possibility of presence or addition of one or more other features, integers, steps, operations, elements, components, or combinations thereof.

Furthermore, when a component is described as being “on” another component, it may be located above or below the other component and does not necessarily imply being positioned on the upper side in the direction of gravity.

When a component is described as being “connected” or “coupled” to another component, it may be directly connected or coupled to the other component or indirectly connected or coupled via another component.

Terms such as “first” and “second” may be used when referring to components, but these terms are intended only for distinguishing one component from another and do not imply any limitation on the nature, order, or sequence of the components.

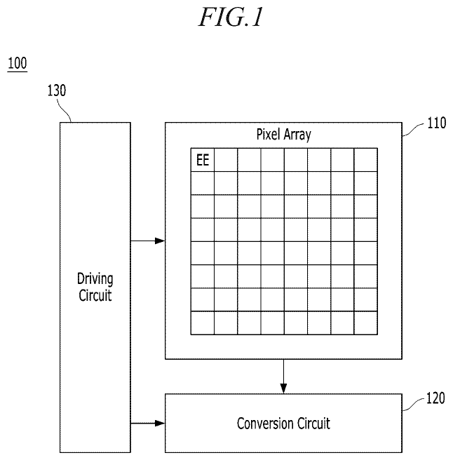

FIG. 1 is a block diagram of an image processing apparatus according to an embodiment of the present disclosure. Referring to FIG. 1, an image processing apparatus 100 includes a pixel array 110, a conversion circuit 120, and a driving circuit 130. It shall be understood that FIG. 1 represents an exemplary block diagram of an image processing apparatus 100 for processing optical signals detected by the pixel array 110, and the structure of the image processing apparatus 100 is not limited to the specific example shown in FIG. 1.

The pixel array 110 includes a plurality of pixels arranged in a two-dimensional grid. Each of the pixels may be configured to detect an external optical signal and generate an analog electrical signal based on the detected optical signal. The pixel array 110 may be controlled by drive signals provided from the driving circuit 130 to generate analog signals. The generated analog signals may be provided to the conversion circuit 120 through column lines connected, respectively, to the plurality of pixels.

Each of the plurality of pixels includes a semiconductor device EE according to an embodiment of the present disclosure. The semiconductor device EE may be configured to generate an analog signal based on an optical signal received from the outside. Furthermore, the semiconductor device EE may be configured to store weight data for applying weights during the conversion of the received optical signal into the analog signal. Under control of the driving circuit 130, the semiconductor device EE may perform operations such as storing or erasing weight data or applying the weight to the received optical signal. In other words, the semiconductor device EE may allow preprocessing of an image within the pixel array 110. The structure and operation of the semiconductor device EE to support this functionality will be described in detail below.

The conversion circuit 120 may be configured to convert the analog signals provided from the pixel array 110 into digital signals. Under control of the driving circuit 130, the conversion circuit 120 may perform various operations for converting the analog signals into the digital signals. For example, the conversion circuit 120 may be configured to perform correlated double sampling to extract valid components of the analog signals under the control of the driving circuit 130.

The analog signal received by the conversion circuit 120 results from the detection of optical signals in the pixel array 110. In addition, the received analog signal may result from reflecting the weight data stored in the semiconductor device EE. That is, the received analog signal may represent a result from preprocessing the image sensed in the pixel array 110. The converted digital signal may be output to an external processor (not shown).

The driving circuit 130 may be configured to control operations of the pixel array 110 for generating an image. The driving circuit 130 may select one or more of a plurality of rows of the pixel array 110. The driving circuit 130 may be configured to control the pixel array 110 and the conversion circuit 120 so that the analog signals generated from the semiconductor devices EE of the selected row(s) are transferred to the conversion circuit 120.

The driving circuit 130 may also be configured to control operations of the pixel array 110 for storing or erasing weight data. The driving circuit 130 may be configured to control the pixel array 110 so that the semiconductor devices EE in the selected row(s) perform a program operation to store the weight data. The driving circuit 130 may also be configured to control the pixel array 110 so that the semiconductor devices EE in the selected row(s) perform an erase operation to delete the stored weight data.

The driving circuit 130 may be configured to control operations of the pixel array 110 for preprocessing images. The driving circuit 130 may be configured to control the pixel array 110 so that the semiconductor devices EE in the selected row(s) perform an operation of converting the detected optical signals into analog electrical signals based on the stored weight data. The driving circuit 130 may also be configured to control the pixel array 110 and the conversion circuit 120 such that the semiconductor devices EE in the selected row(s) perform a read operation of outputting the weighted analog signals to the conversion circuit 120.

The driving circuit 130 may be configured to control an operation for converting the analog signal transmitted to the conversion circuit 120 into a digital signal. The driving circuit 130 may be configured to control temporary storage and output of the digital signal. The driving circuit 130 may be configured to generate a clock signal and a timing control signal for the series of operations described above, and the generated clock signal and timing control signal may be provided to the pixel array 110 and the conversion circuit 120.

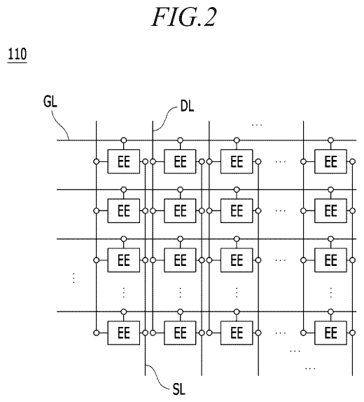

FIG. 2 is a circuit diagram of the pixel array shown in FIG. 1. Referring to FIG. 2, the pixel array 110 includes a plurality of pixels arranged in a two-dimensional grid. Each of the pixels includes a semiconductor device EE capable of detecting an optical signal and converting the optical signal into an analog electrical signal as well as preprocessing the analog signal. The semiconductor device EE is connected to a gate line GL, a source line SL, and a drain line DL.

The gate line GL is electrically connected to a gate of the semiconductor device EE. The gate line GL may extend in a row direction and may be provided as a plurality of lines arranged in a column direction within the pixel array 110. The gate line GL may be shared among the pixels in the same row and may be connected to the driving circuit 130 shown in FIG. 1. The driving circuit 130 may apply a gate voltage to the semiconductor device EE via the gate line GL.

The gate voltage may be applied to the semiconductor device EE via the gate line GL to perform a program operation or an erase operation. The gate voltage applied to the semiconductor device EE to be programmed may be at a program voltage level that is higher than the voltage level of the drain line DL. The gate voltage applied to the semiconductor device EE to be erased may be at an erase voltage level that is lower than the voltage level of the drain line DL.

The gate voltage may be applied to the semiconductor device EE via the gate line GL to generate and output an image based on an external optical signal. In such a read operation, the gate voltage applied to the semiconductor device EE may be at a read voltage level that is higher than the voltage level of the drain line DL. The read voltage level may be lower than the program voltage level.

Furthermore, the gate voltage may be applied to the semiconductor device EE via the gate line GL to perform a program operation based on an external optical signal. As in the program operation described above, the gate voltage may be at a program voltage level that is higher than the voltage level of the drain line DL. Additionally, the external environment of the semiconductor device EE may be in a state capable of receiving an optical signal.

The drain line DL is electrically connected to a drain of the semiconductor device EE. The drain line DL may extend in a column direction and may be provided as a plurality of lines arranged in a row direction within the pixel array 110. The drain line DL may be shared among the pixels in the same column. Based on the voltages applied to the gate line GL and the voltages applied to the drain line DL, weight data required for each of the two-dimensionally arranged semiconductor devices EE may be stored. The drain line DL may be connected to the driving circuit 130 shown in FIG. 1. The driving circuit 130 may be configured to apply a drain voltage to the semiconductor device EE via the drain line DL.

The drain voltage may be applied to the semiconductor device EE via the drain line DL to perform a program operation, an erase operation, or a read operation. The voltage level of the drain line DL applied to the semiconductor device EE to be programmed may be lower than the program voltage level. The voltage level of the drain line DL applied to the semiconductor device EE to be erased may be higher than the erase voltage level. In the case of the read operation, the voltage level of the drain line DL may be lower than the read voltage level. To facilitate charge movement in the channel of the semiconductor device EE, the voltage level of the drain line DL may be lower than that of the source line SL.

The source line SL is electrically connected to a source of the semiconductor device EE. The source line SL may extend in the column direction and may be provided as a plurality of lines arranged in the row direction within the pixel array 110. The source line SL may be shared among the pixels in the same column. The source line SL may be connected to the conversion circuit 120 shown in FIG. 1. The conversion circuit 120 may be configured to receive the analog signal or a weighted analog signal via the source line SL.

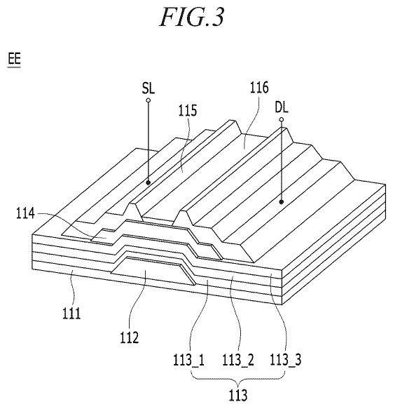

FIG. 3 is a perspective view of the semiconductor device shown in FIGS. 1 and 2. Referring to FIG. 3, the semiconductor device EE includes a base substrate 111, a first electrode layer 112, a charge storage layer 113, an active layer 114, a second electrode layer 115, and a photo-sensitive layer 116. For convenience of explanation, FIG. 3 is described with reference to the reference numerals used in FIG. 2.

The base substrate 111 is configured to physically and stably support the stacked structures disposed thereon. The base substrate 111 may be an insulator. The base substrate 111 may be a substrate including silicon or silicon oxide (e.g., SiO₂), but is not limited thereto.

The first electrode layer 112 is disposed on the base substrate 111 and includes a conductive material. The first electrode layer 112 functions as the gate electrode of the semiconductor device EE and is electrically connected to the gate line GL shown in FIG. 2. The first electrode layer 112 may be configured to receive a gate voltage through the gate line GL. The gate voltage is used for the program, erase, and read operations of the semiconductor device EE. To provide a region that receives an optical signal at an uppermost portion of the semiconductor device EE, the gate electrode is disposed beneath the charge storage layer 113, the active layer 114, and the second electrode layer 115, which will be described later. That is, the semiconductor device EE according to an embodiment of the present disclosure may have a bottom-gate top-contact (BGTC) structure.

The charge storage layer 113 is disposed on the first electrode layer 112 and the base substrate 111. At least a portion of the charge storage layer 113 is disposed to overlap, in a planar view, the first electrode layer 112 and the base substrate 111 and to be in contact with the first electrode layer 112. Another portion of the charge storage layer 113 is disposed, in a planar view, to not overlap the first electrode layer 112 and to be in contact with the base substrate 111.

The charge storage layer 113 is configured to store charge injected in response to the gate voltage applied to the first electrode layer 112. During a program operation, a high gate voltage level causes electrons present in the active layer 114 to be trapped in the charge storage layer 113. During an erase operation, a low gate voltage level causes the electrons trapped in the charge storage layer 113 to be released into the active layer.

The charge stored in the charge storage layer 113 may be defined as the weight data described above. The weight data that can be stored by the charge storage layer 113 may have multi-level characteristics of 4 bits or more, and the semiconductor device EE may be, for example, a multi-level cell (MLC). However, the semiconductor device EE is not limited thereto and may also be a single-level cell (SLC).

The charge storage layer 113 includes a blocking layer 113_1, a charge trapping layer 113_2, and a tunneling layer 113_3 to perform the function of trapping charge. The blocking layer 113_1, the charge trapping layer 113_2, and the tunneling layer 113_3 may include at least one metal oxide. For example, such a metal oxide may be represented as MₓO_{γ}, a compound of a metal M with cations and oxygen, where the metal M may include alkali metals (Li, Na, K, Rb, etc.), alkaline earth metals (Mg, Ca, Sr, Ba, etc.), transition metals (Zr, Nb, Ta, W, etc.), lanthanide metals (Pr, Nd, Sm, Eu, etc.), other metals (Al, Ga, In, Sn, etc.), or combinations thereof.

The blocking layer 113_1, the charge trapping layer 113_2, and the tunneling layer 113_3 may be formed by high vacuum deposition at a thickness ranging from 0.5 nm to 50 nm. However, the thickness of each layer is not limited thereto. The high vacuum deposition may include thermal deposition, flash deposition, laser deposition, atomic layer deposition, or physical vapor deposition.

The blocking layer 113_1 is disposed between the first electrode layer 112 and the active layer 114, and more specifically, between the first electrode layer 112 and the charge trapping layer 113_2. The blocking layer 113_1 is configured to block the movement of charge trapped in the charge trapping layer 113_2 to the first electrode layer 112.

For example, the blocking layer 113_1 may include aluminum oxide (AlOx). The aluminum oxide (AlOx) may be formed using a thermal atomic layer deposition process, for example, at a temperature of approximately 250° C., and may be an amorphous oxide layer including Al₂O₃. However, the blocking layer 113_1 is not limited thereto and may include a material having a bandgap energy higher than that of the charge trapping layer 113_2 to block charge from moving to the first electrode layer 112. For example, the blocking layer 113_1 may also include tantalum oxide (TaOx). The blocking layer 113_1 may be formed using a plasma-enhanced atomic layer deposition process, for example, at a temperature of approximately 225° C., and may be an amorphous oxide layer including Ta₂O₅.

The charge trapping layer 113_2 is disposed between the blocking layer 113_1 and the active layer 114, and more specifically, between the blocking layer 113_1 and the tunneling layer 113_3. The charge trapping layer 113_2 is configured to trap charge injected from the active layer 114 in response to the gate voltage.

For example, the charge trapping layer 113_2 may include niobium oxide (NbOx). The niobium oxide (NbOx) may be deposited using a sputtering process, for example, at a deposition temperature of approximately 200° C., and may be an amorphous oxide layer including various suboxides such as NbO₂ and NbO along with Nb₂O₅. The niobium oxide (NbOx) may be disposed on the aluminum oxide (AlOx). However, the charge trapping layer 113_2 is not limited thereto and may include a material having a bandgap energy lower than that of the blocking layer 113_1 as long as it can trap charge.

The tunneling layer 113_3 is disposed between the charge trapping layer 113_2 and the active layer 114. The tunneling layer 113_3 is configured to control the movement of charge between the charge trapping layer 113_2 and the active layer 114 depending on the gate voltage. When a high positive or negative gate voltage is applied and there is a large difference in bandgap energy between the charge trapping layer 113_2 and the active layer 114, for example, during the program operation or the erase operation, the band slope of the tunneling layer 113_3 changes. Due to tunneling associated with this change, charge may move between the charge trapping layer 113_2 and the active layer 114. Otherwise, the tunneling layer 113_3 is configured to act as an energy barrier.

For example, the tunneling layer 113_3 may include an oxide such as silicon oxide (SiOx), although it is not limited thereto and may include any material capable of serving as an energy barrier layer. The detailed operations of charge trapping and release in the semiconductor device EE associated with the charge storage layer 113 will be described later.

The active layer 114 is disposed on the charge storage layer 113. The active layer 114 is disposed to overlap the charge storage layer 113 in a planar view and is in contact with the charge storage layer 113. At least a portion of the active layer 114 is disposed to overlap the first electrode layer 112 in a planar view. The first electrode layer 112 and the active layer 114 are disposed to face each other with the charge storage layer 113 interposed therebetween. The active layer 114 is in contact with the second electrode layer 115.

The active layer 114 is configured to form a channel for movement of charge between the source line SL and the drain line DL, which are electrically connected to the second electrode layer 115. Charge present in the active layer 114 may be injected into the charge storage layer 113 based on a gate voltage at a program voltage level applied to the first electrode layer 112. Charge trapped in the charge storage layer 113 may be released into the active layer 114 based on a gate voltage at an erase voltage level.

The active layer 114 may include a metal oxide or an organic material with semiconductor properties for forming the channel. For example, such a metal oxide may be a compound MₓO_{γ} composed of a metal M with cations and oxygen, where the metal M may include alkali metals (Li, Na, K, Rb, etc.), alkaline earth metals (Mg, Ca, Sr, Ba, etc.), transition metals (Zr, Nb, Ta, W, etc.), lanthanide metals (Pr, Nd, Sm, Eu, etc.), other metals (Al, Ga, In, Sn, etc.), or combinations thereof. In one example, the organic material may include anthracene, tetracene, pentacene, fullerene, polythiophenes, phthalocyanine, perylene, poly(3-hexylthiophene) (P3HT), poly(phenylenevinylene) (PPV), poly(9,9-dioctylfluorene-co-bithiophene) (F8T2), regio-regular poly(thiophene) (XPT), or combinations thereof.

The second electrode layer 115 is disposed on the active layer 114. The second electrode layer 115 is disposed in contact with the active layer 114 to be electrically connected to the channel formed in the active layer 114. At least a portion of the second electrode layer 115 is disposed to overlap the active layer 114 in a planar view. Another portion of the second electrode layer 115 is disposed not to overlap the active layer 114 in a planar view and to be in contact with the charge storage layer 113.

The second electrode layer 115 includes a source electrode electrically connected to the source line SL and a drain electrode electrically connected to the drain line DL. The source electrode is disposed to be in contact with a first portion of the active layer 114. The source electrode is disposed to overlap with the first portion of the active layer 114. The drain electrode is disposed to be in contact with a second portion of the active layer 114 that is different from the first portion. The drain electrode is disposed to overlap with the second portion. The source electrode and the drain electrode are disposed not to overlap each other in a planar view. Based on a potential difference between the source electrode and the drain electrode, an analog signal or a weighted analog signal may be transferred to the source line SL.

The photo-sensitive layer 116 is disposed on the active layer 114 and may be positioned at the substantially topmost part of the laminated structure of the semiconductor device EE. At least a portion of the photo-sensitive layer 116 is disposed to overlap, in a planar view, with the first electrode layer 112, the charge storage layer 113, and the active layer 114, and is disposed not to overlap with the second electrode layer 115. The photo-sensitive layer 116 is configured to generate charge based on an external optical signal.

The photo-sensitive layer 116 may be configured to generate charge according to the amount or intensity of the detected light. The generated charge is transferred to the active layer 114 and may be output from the semiconductor device EE through the source line SL as an analog signal. Although the photo-sensitive layer 116 may be configured to detect optical signals in the visible light spectrum, it is not limited thereto. For example, the photo-sensitive layer 116 may also detect optical signals in at least one of the spectral bands such as infrared, ultraviolet, and X-ray.

The photo-sensitive layer 116 may be disposed on the active layer 114 so as to overlap with the charge storage layer 113 and the channel formed by the active layer 114. As will be described in more detail below, the charge trapped in the charge storage layer 113 functions as a type of weight that modulates the current flowing in response to the optical signal. To fulfill this function, the charge storage layer 113 must be located in a position capable of influencing the channel through which charge is transferred by the photo-sensitive layer 116. In other words, the photo-sensitive layer 116 overlaps with the active layer 114 and the charge storage layer 113 such that the photo-sensitive layer 116 transfers charge to the channel region overlapping with the charge storage layer 113.

To ensure high light absorption characteristics, the photo-sensitive layer 116 may include at least one of an organic semiconductor, silicon, a metal oxide, and colloidal inorganic quantum dots. For example, the organic semiconductor may include polymers, fullerenes and their derivatives, non-fullerene molecules, and small molecules. The silicon may include single-crystal silicon, polycrystalline silicon, nanocrystalline silicon, and amorphous silicon. The metal oxide may be an MₓO_{γ} material composed of a metal M having cations and oxygen, where the metal M may include alkali metals (Li, Na, K, Rb, etc.), alkaline earth metals (Mg, Ca, Sr, Ba, etc.), transition metals (Zr, Nb, Ta, W, etc.), lanthanide metals (Pr, Nd, Sm, Eu, etc.), other metals (Al, Ga, In, Sn, etc.), or combinations thereof. The colloidal inorganic quantum dots may include any nanoparticles exhibiting metallic, semiconducting, or insulating properties. The photo-sensitive layer 116 including quantum dots will be described later in more detail.

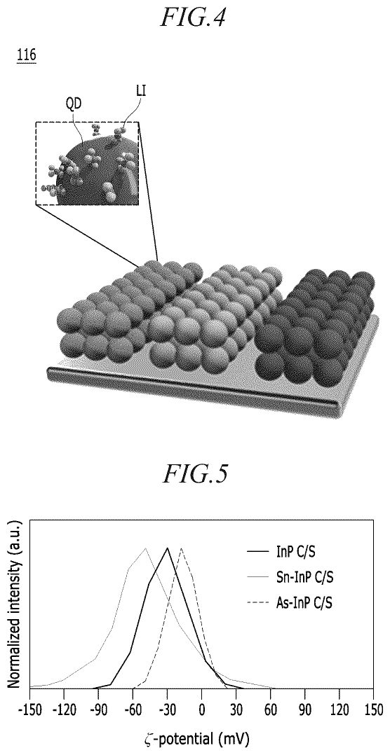

FIG. 4 illustrates an embodiment of the photo-sensitive layer shown in FIG. 3. Referring to FIG. 4, the photo-sensitive layer 116 according to an embodiment of the present disclosure includes a quantum dot layer. The quantum dot layer includes quantum dots QD having inorganic ligands LI formed on a surface thereof. The quantum dots QD may be disposed on the active layer 114 of FIG. 3 and configured to detect external light. When a quantum dot QD receives an optical signal, an electron-hole pair is generated and transferred to the active layer 114, and the conductivity of the active layer 114 may be increased by the transferred electron-hole pair.

The quantum dots QD include semiconductor materials in the form of nanoparticles. However, they are not limited thereto and may also include metallic or insulating nanoparticles. For example, the quantum dots QD may include nanoparticles made of II-VI compounds, III-V compounds, IV-VI compounds, group IV elements or compounds, II-III-VI compounds, I-III-VI compounds, I-II-III-V-VI compounds, metal halide perovskite compounds, transition metal chalcogenide perovskite compounds, or combinations thereof.

Ligands LI may be formed on the surfaces of the quantum dots QD. Quantum dots QD with inorganic ligands LI may exhibit high light absorption and may detect optical signals across a broad wavelength range from ultraviolet (UV) to near-infrared (NIR). Quantum dots with organic ligands, due to their long insulating chains, exhibit lower charge mobility compared to those with inorganic ligands. According to an embodiment of the present disclosure, a ligand exchange process may be performed to replace organic ligands of quantum dots QD with inorganic ligands to enhance electron mobility. Furthermore, quantum dots QD with inorganic ligands LI may exhibit thin-film nonuniformity, which may be improved by forming hetero-inorganic ligands LI on the surface of the quantum dots QD.

For example, the quantum dot layer may include colloidal inorganic quantum dots. The colloidal inorganic quantum dots may have quantum dots QD with organic or inorganic ligands LI and any nanomaterials using water or an organic solvent as a dispersion medium.

In an example, the organic ligand LI of the quantum dot QD may be a compound having a first functional group and a carbon chain. The first functional group may include a carboxyl group, thiol group, amino group, amide group, phosphine group, phosphine oxide group, ester group, hydroxyl group, or combinations thereof, and may be in a charged state. The carbon chain may include substituted or unsubstituted aliphatic hydrocarbon groups with 5 to 40 carbon atoms, substituted or unsubstituted alkyl groups with 5 to 40 carbon atoms, substituted or unsubstituted aromatic hydrocarbon groups with 10 to 50 carbon atoms, substituted or unsubstituted heteroarylene groups with 5 to 30 atoms, substituted or unsubstituted heterocyclic groups with 5 to 40 atoms, or combinations thereof.

The ligand LI may include hetero-inorganic materials. For example, the inorganic ligand LI for the quantum dot QD may include alkali metals, alkaline earth metals, nitrogen, chalcogens, halogens, metal chalcogenide complexes, or combinations thereof. The metal chalcogenide complexes may include combinations of three different inorganic elements forming II-IV-VI (e.g., ZnSn₂S₆²⁻, CuSn₂S₆²⁻, CdSn₂S₆²⁻, ZnSn₂Se₆²⁻, CuSn₂Se₆²⁻, CdSn₂Se₆²⁻, ZnSn₂Te₆²⁻, CuSn₂Te₆²⁻, CdSn₂Te₆²⁻, and combinations thereof), III-IV-VI (e.g., GaSn₂S₆⁻, InSn₂S₆⁻, GaSn₂Se₆⁻, InSn₂Se₆⁻, GaSn₂Te₆, InSn₂Te₆, and combinations thereof), II-V-VI (e.g., ZnSb₂S₆, CdSb₂S₆, ZnSb₂Se₆, CdSb₂Se₆⁺, ZnSb₂Te₆⁺, CdSb₂Te₆⁺, and combinations thereof), and III-V-VI (e.g., GaSb₂S₆⁺, InSb₂S₆⁺, GaSb₂Se₆⁺, InSb₂Se₆⁺, GaSb₂Te₆⁺, InSb₂Te₆⁺, and combinations thereof).

FIG. 5 is a graph illustrating the effects of introducing inorganic ligands into quantum dots as applied in FIG. 4. Referring to FIG. 5, the horizontal axis represents the zeta potential, and the vertical axis represents light intensity. That is, FIG. 5 may be understood as showing light-absorption spectra with respect to zeta potential.

“InP C/S” represents the intensity spectrum with respect to zeta potential for quantum dots having organic ligands. “Sn—InP C/S” and “AS-InP C/S” respectively represent the intensity spectra with respect to zeta potential for quantum dots into which inorganic ligands based on Sn₂S₆⁴⁻ and AsS₃³⁻ have been introduced. According to the waveforms shown in FIG. 5, the introduction of inorganic ligands results in higher absorption intensity at lower zeta potentials. Lower zeta potential corresponds to higher charge mobility, and thus, quantum dots with inorganic ligands introduced thereto may exhibit higher charge mobility compared to those with organic ligands.

In other words, according to an embodiment of the present disclosure, since the photo-sensitive layer 116 including quantum dots QD with ligands LI formed thereon, as shown in FIG. 4, may exhibit higher charge mobility, the amount of charge moving to the active layer 114 upon detection of an optical signal increases. Accordingly, the quality of the analog signal generated based on the optical signal is improved, and high photosensitivity can be achieved. In particular, according to an embodiment of the present disclosure, the semiconductor device EE, which generates analog signals, is also required to perform a weighting operation in addition to image sensing. In such a case, quantum dots QD with inorganic ligands introduced thereto may enable high-quality image generation owing to their high photosensitivity, thereby allowing immediate preprocessing using weight data.

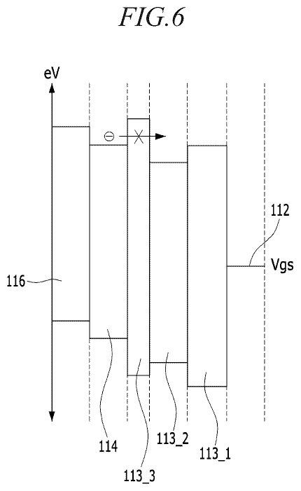

FIG. 6 is an energy band diagram of the semiconductor device of FIG. 3 in a state where no gate voltage is applied. Referring to FIG. 6, the energy bands corresponding to the first electrode layer 112, the blocking layer 113_1, the charge trapping layer 113_2, the tunneling layer 113_3, the active layer 114, and the photo-sensitive layer 116 are shown. For convenience of explanation, the reference numerals of FIG. 3 are used in the following description of FIG. 6.

In the semiconductor device EE, when a gate-source voltage Vgs is not applied to the first electrode layer 112, the charge present in the active layer 114 is blocked by the tunneling layer 113_3 and cannot move to the charge trapping layer 113_2. Likewise, the charge stored in the charge trapping layer 113_2 cannot move to the active layer 114 due to the tunneling layer 113_3.

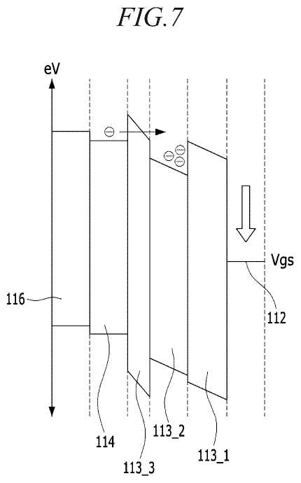

FIG. 7 is an energy band diagram of the semiconductor device of FIG. 3 during a program operation. The energy bands correspond to the same components shown in FIG. 6. Referring to FIG. 7, during the program operation, a gate voltage at a program voltage level is applied to the first electrode layer 112. The program voltage level is higher than the voltage level of the source voltage. The program voltage level may be a positive voltage, and the gate-source voltage Vgs may be positive.

When a positive gate-source voltage Vgs is applied, the energy bandgap difference between the charge trapping layer 113_2 and the active layer 114 increases. Moreover, the energy band slope of the tunneling layer 113_3 changes. Accordingly, charges present in the active layer 114 can move through the tunneling layer 113_3 to the charge trapping layer 113_2. That is, the charges become stored in the charge trapping layer 113_2, representing a programmed state.

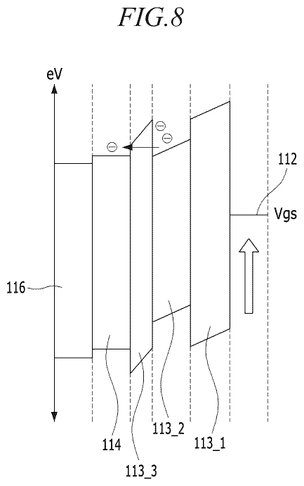

FIG. 8 is an energy band diagram of the semiconductor device of FIG. 3 during an erase operation. The energy bands correspond to the same components shown in FIG. 6. Referring to FIG. 8, during the erase operation, a gate voltage Vgs at an erase voltage level is applied to the first electrode layer 112. The erase voltage level is lower than the voltage level of the source voltage. The erase voltage level may be a negative voltage, and the gate-source voltage Vgs may be negative.

When a negative gate-source voltage Vgs is applied, unlike in the program operation, the energy bandgap difference between the charge trapping layer 113_2 and the active layer 114 is reversed. In addition, the band slope of the tunneling layer 113_3 is also reversed compared to FIG. 7. Accordingly, charges stored in the charge trapping layer 113_2 can move through the tunneling layer 113_3 to the active layer 114. That is, the charges stored in the charge trapping layer 113_2 are released, representing an erased state.

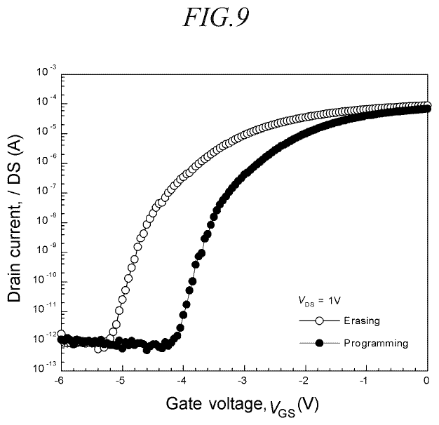

FIG. 9 is a graph illustrating the effect of the program operation of FIG. 7 and the erase operation of FIG. 8. Referring to FIG. 9, the horizontal axis is defined as the magnitude of the gate-source voltage Vgs described in FIGS. 7 and 8, and the vertical axis is defined as the magnitude of the drain-source current Ids flowing between the source and drain, i.e., through the active layer 114 described above. For convenience of description, FIG. 9 is described with reference to the reference numerals used in FIG. 7 or 8.

The magnitude of the drain-source current Ids in response to the gate-source voltage Vgs in the program state is smaller than the magnitude of the drain-source current Ids in response to the gate voltage Vgs in the erased state. Moreover, the magnitude of the gate-source voltage Vgs at which the drain-source current Ids sharply increases is smaller in the erased state than in the program state.

In other words, the charges stored in the charge trapping layer 113_2 influence the conductivity of the channel formed in the active layer 114. Accordingly, when an analog signal is generated by detecting an optical signal via the photo-sensitive layer 116, the charges stored in the charge trapping layer 113_2 function as weight data. The analog signal is generated based on the intensity of the detected optical signal and the weight data resulting from the program or erase operation. The analog signal has a current level that depends on the amount of charge provided to the active layer 114 by the optical signal and the amount of charge stored in the charge trapping layer 113_2.

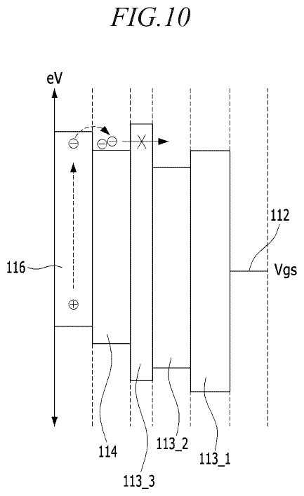

FIG. 10 is an energy band diagram of the semiconductor device shown in FIG. 3 during a light-receiving operation. FIG. 10 shows the energy bands of the same components as those in FIG. 6. Referring to FIG. 10, in the light-receiving operation, the photo-sensitive layer 116 detects optical signals. A gate voltage of the same level as that used in the program or erase operation is not applied to the first electrode layer 112. However, a drain voltage at a read voltage level may be applied to enable the output of an analog signal generated based on the optical signal. The read voltage level may be a positive voltage, and the gate-source voltage Vgs may also be a positive voltage.

When an optical signal above a certain intensity is supplied from the outside, the photo-sensitive layer 116 converts the optical signal into an electrical signal. For example, the photo-sensitive layer 116 may be a quantum dot layer. In such a case, the quantum dots generate electron-hole pairs in response to the optical signal. Depending on the bandgap energy difference between the photo-sensitive layer 116 and the active layer 114, electrons move to the active layer 114, while holes are blocked by a barrier and cannot move to the active layer 114.

If a gate voltage Vgs at the program level is not applied, the charges transferred from the photo-sensitive layer 116 to the active layer 114 cannot move to the charge trapping layer 113_2 due to the tunneling layer 113_3. However, since the conductivity of the active layer 114 depends on the amount of charge stored in the charge trapping layer 113_2, the analog signal generated based on the optical signal may be influenced by the programmed weight data. Once the supply of the optical signal stops, the electrons moved to the active layer 114 may not be stored and may return to the initial state.

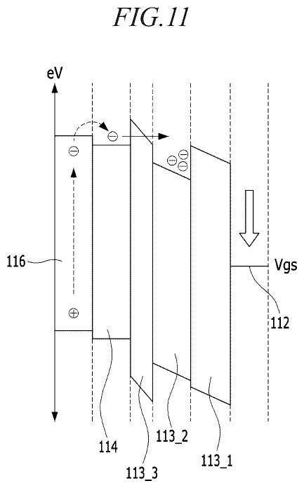

FIG. 11 is an energy band diagram of the semiconductor device shown in FIG. 3 during light-receiving and program operations. FIG. 11 shows the energy bands of the same components as those in FIG. 6. Referring to FIG. 11, in the light-receiving operation, the photo-sensitive layer 116 detects an optical signal. Simultaneously, a gate voltage at a program voltage level is applied to the first electrode layer 112 for the program operation. The program voltage level may be a positive voltage, and the gate-source voltage Vgs may be a positive voltage.

The photo-sensitive layer 116 converts the optical signal into an electrical signal. Charges generated in the photo-sensitive layer 116 move to the active layer 114. Moreover, under the applied positive gate-source voltage Vgs, the charges moved to the active layer 114 may move through the tunneling layer 113_3 to the charge trapping layer 113_2. That is, data may be stored in the semiconductor device EE based on the detected optical signal. Depending on how the semiconductor device EE is controlled and utilized, weight data may be generated based on the detected optical signal. In other words, within a single device, the weight data may be generated in various ways using either light or electricity. This weight data may also be implemented to apply a weight to an analog signal generated by light or electricity.

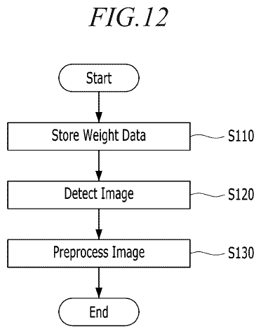

FIG. 12 is a flowchart illustrating a method for operating the image processing apparatus according to an embodiment of the present disclosure. The method for operating the image processing apparatus shown in FIG. 12 may be performed in the image processing apparatus 100 shown in FIG. 1. For convenience of description, FIG. 12 is described with reference to the reference numerals of FIGS. 1 through 3.

In step S110, the image processing apparatus 100 may perform an operation to store weight data. For example, the driving circuit 130 may apply a voltage at a program voltage level to the gate lines GL connected to the pixels corresponding to the row to be programmed with the weight data in the pixel array 110. Through the drain voltage applied to the drain lines DL, the driving circuit 130 may determine the gate-source voltage Vgs for each column of the semiconductor devices EE to which the voltage level is applied. In other words, the semiconductor device EE may determine the weight data to be programmed to each of the pixels based on the voltage levels of the gate line GL and the drain line DL electrically connected thereto.

When a gate voltage at the program voltage level is applied through the first electrode layer 112 of the semiconductor device EE, charges present in the channel formed in the active layer 114 are injected into the charge storage layer 113. The charges present in the active layer 114 are trapped in the charge trapping layer 113_2 through the tunneling layer 113_3. The trapped charges influence the conductivity of the channel. The trapped charges will be understood as weight data that affect the magnitude of the analog signal when the analog signal is generated later based on the optical signal.

As the driving circuit 130 performs the program operation for all rows of the pixel array 110, weight data for all pixels may be set. The weight data may be used for preprocessing image data. The weight data may be used to increase the intensity of the analog signal to emphasize important parts in a detected image. The weight data may be used to decrease the intensity of the analog signal in regions of the detected image that are less important, require lower resolution, or need to be filtered.

In step S120, the image processing apparatus 100 may perform an operation to detect an image. The pixel array 110 may generate analog signals based on external optical signals. The driving circuit 130 may apply a voltage at a read voltage level to the gate lines GL connected to the pixels corresponding to the row to which the analog signals are to be output to the conversion circuit 120. The driving circuit 130 may apply a voltage to the drain lines DL to allow current to flow through the source lines SL.

The photo-sensitive layer 116 of the semiconductor device EE generates an analog electrical signal based on the external optical signal. The photo-sensitive layer 116 may form electron-hole pairs in response to the optical signal, and the electrons may move to the active layer 114. That is, the charges generated in the photo-sensitive layer 116 may move to the active layer 114 and then to the second electrode layer 115, whereby the analog signal may be transmitted to the conversion circuit 120.

As a result of all pixels detecting the image, image data may be generated. The analog signals detected by the pixels in the pixel array 110 based on the optical signals may be understood as image data. The image data may be output to the conversion circuit 120 via the source lines SL on a row-by-row basis. Moreover, the image data may be preprocessed before being output to the conversion circuit 120.

In step S130, the image processing apparatus 100 may perform an operation to preprocess the image. The analog signals generated by the pixel array 110 are preprocessed based on the weight data set for each pixel. In step S120, the driving circuit 130 may apply a voltage at the read voltage level to the gate lines GL corresponding to the row outputting the analog signals. The driving circuit 130 applies a voltage to the drain lines DL to form channels in the semiconductor devices EE. The conductivity of the channels depends on the weight data set for each pixel.

The conductivity of the channel formed in the active layer 114 is determined according to the amount of charge stored in the charge storage layer 113. The intensity of the analog signal is determined based on the intensity of the optical signal and the charge stored in the charge storage layer 113. Even if the optical signal is weak, if a high weight is reflected in the analog signal based on the charge stored in the charge storage layer 113, the magnitude of the analog signal may be relatively increased. Even if the optical signal is strong, the magnitude of the analog signal may be relatively reduced if a low weight is reflected in the analog signal.

As the weight data is determined, the semiconductor device EE according to an embodiment of the present disclosure can be utilized as a kernel-type array device for optical signal inference. For example, assuming that the original image has a size of N×N and the kernel array has a size of M×M (where N>M), the M×M kernel moves one pixel at a time across the original image while receiving optical signals. By calculating current output as the kernel moves across different parts of the image, an output image of size (N−M+1)×(N−M+1) can ultimately be obtained. This technique is based on the concept of the kernel sequentially processing each region of the image to extract and transmit the necessary information. Through preprocessing using a kernel, which is a small matrix for extracting or transforming specific features of an image, the semiconductor device EE can play a key role in various applications such as image recognition, edge detection, and pattern recognition.

As the image data is preprocessed using the weight data, the utility of the image may be enhanced. For example, in the case of a CCTV, to improve the visibility of regions with poor lighting, the weights for the corresponding pixels may be preset high during step S110. In another example, for regions requiring close monitoring, such as high foot traffic, higher weights can be preset to enhance visibility in CCTV images. Conversely, for regions requiring less attention, such as ceilings or the sky, lower weights can be preset for filtering purposes in CCTV images. Through such preprocessing, images with higher monitoring demand are emphasized, while images with lower monitoring demand are filtered, thereby increasing the overall utility of the output image.

While certain exemplary embodiments have been described, it shall be appreciated by those skilled in the art that various modifications and alterations are possible without departing from the technical ideas and scope of the disclosure as set forth in the claims below. The embodiments disclosed herein are not intended to limit the technical ideas of the present disclosure, and all technical concepts and ideas falling within the scope of the claims and their equivalents are to be construed as being within the scope of the present disclosure.

1. A semiconductor device comprising:
a base substrate;
a first electrode layer disposed on the base substrate;
a charge storage layer disposed on the first electrode layer and the base substrate and configured to store charges injected by a gate voltage applied to the first electrode layer;
an active layer disposed on the charge storage layer and configured to inject charges into the charge storage layer based on the gate voltage;
a second electrode layer disposed to be in contact with a portion of the active layer so as to be electrically connected to the active layer; and
a photo-sensitive layer disposed on the active layer so as to at least partially overlap with the active layer and the charge storage layer and configured to provide charges to the active layer based on an optical signal.

2. The semiconductor device of claim 1, wherein the photo-sensitive layer comprises a quantum dot layer including a semiconductor material in the form of nanoparticles.

3. The semiconductor device of claim 2, wherein the quantum dot layer comprises quantum dots having ligands formed on surfaces thereof, and
wherein the ligands comprise a combination of heterogeneous inorganic materials.

4. The semiconductor device of claim 2, wherein the quantum dot layer comprises colloidal inorganic quantum dots, wherein ligands including organic and inorganic materials are formed on surfaces of the colloidal inorganic quantum dots, and the colloidal inorganic quantum dots are dispersed by a dispersion medium including water or an organic solvent.

5. The semiconductor device of claim 1, wherein the charge storage layer comprises:
a blocking layer disposed between the first electrode layer and the active layer and configured to block movement of charges injected from the active layer to the first electrode layer;
a charge trapping layer disposed between the blocking layer and the active layer and configured to trap charges injected from the active layer; and
a tunneling layer disposed between the charge trapping layer and the active layer and configured to control movement of charges between the charge trapping layer and the active layer according to the gate voltage.

6. The semiconductor device of claim 1, wherein, when the gate voltage applied to the first electrode layer is a program voltage level that is higher than a voltage level of the second electrode layer, charges are injected from the active layer into the charge storage layer.

7. The semiconductor device of claim 6, wherein, when the gate voltage is the program voltage level and charges are provided from the photo-sensitive layer to the active layer based on the optical signal, the charges provided to the active layer are injected into the charge storage layer.

8. The semiconductor device of claim 1, wherein, when the gate voltage applied to the first electrode layer is an erase voltage level that is lower than a voltage level of the second electrode layer, charges are released from the charge storage layer to the active layer.

9. The semiconductor device of claim 1, wherein, when the gate voltage applied to the first electrode layer is a read voltage level that is lower than a program voltage level at which charges are injected from the active layer into the charge storage layer, charges are provided from the photo-sensitive layer to the active layer based on the optical signal and move to the second electrode layer through the active layer.

10. The semiconductor device of claim 1, wherein a magnitude of current flowing in the second electrode layer through the active layer depends on an intensity of the optical signal and an amount of charge trapped in the charge storage layer.

11. An image processing apparatus comprising:
a pixel array comprising pixels, each of the pixels having a semiconductor device configured to generate an analog signal, which is an electrical signal, based on an optical signal;
a conversion circuit configured to convert the analog signal into a digital signal; and
a driving circuit configured to control a voltage applied to the pixel array,
wherein the semiconductor device comprises:
a photo-sensitive layer configured to convert the optical signal into the electrical signal;
a charge storage layer in which charges are trapped to adjust a magnitude of the electrical signal; and
an active layer disposed between the photo-sensitive layer and the charge storage layer and forming a channel for transferring the analog signal to the conversion circuit based on the voltage controlled by the driving circuit.

12. The image processing apparatus of claim 11, further comprising:
a gate line connected between the driving circuit and the pixel array and configured to receive a gate voltage for controlling formation of the channel from the driving circuit and transfer the gate voltage to the semiconductor device;
a drain line connected between the driving circuit and the pixel array and configured to receive a drain voltage for supplying charges to the channel from the driving circuit and transfer the drain voltage to the semiconductor device; and
a source line connected between the pixel array and the conversion circuit and configured to transfer the analog signal to the conversion circuit.

13. The image processing apparatus of claim 12, wherein the semiconductor device further comprises:
a gate electrode electrically connected to the gate line and disposed to face the active layer with the charge storage layer interposed therebetween;
a source electrode electrically connected to the source line and disposed on the charge storage layer and the active layer to contact a first portion of the active layer; and
a drain electrode electrically connected to the drain line and disposed on the charge storage layer and the active layer to contact a second portion of the active layer, the second portion being different from the first portion.

14. The image processing apparatus of claim 12, wherein the driving circuit is configured to control a voltage level of the gate voltage to inject charges from the active layer into the charge storage layer or to release charges from the charge storage layer into the active layer.

15. The image processing apparatus of claim 12, wherein the driving circuit is configured to apply a drain voltage to a pixel connected to the drain line and to apply the gate voltage having a program voltage level that is higher than the drain voltage through a gate line connected to the pixel to store weight data in the pixel.

16. The image processing apparatus of claim 15, wherein the driving circuit is configured to apply the gate voltage having a read voltage level that is lower than the program voltage level and to apply the drain voltage for a current flow in the channel, and
wherein the semiconductor device is configured to output the analog signal to the conversion circuit based on the gate voltage at the read voltage level.

17. The image processing apparatus of claim 11, wherein the analog signal has a current magnitude dependent on an amount of charge provided to the active layer by the optical signal and an amount of charge trapped in the charge storage layer.

18. A method for operating an image processing apparatus comprising a pixel array including a semiconductor device configured to generate an analog signal, which is an electrical signal, based on an optical signal, and a driving circuit configured to control a voltage applied to the pixel array, the method comprising:
applying, by the driving circuit, a gate voltage at a program voltage level to the semiconductor device to store weight data in a charge storage layer of the semiconductor device;
detecting an image by providing, by a photo-sensitive layer of the semiconductor device, charges to an active layer of the semiconductor device based on the optical signal; and
preprocessing the image by generating the analog signal based on the weight data and the charges provided to the active layer.

19. The method of claim 18, wherein the storing of the weight data comprises:
applying, by the driving circuit, the gate voltage to a gate electrode of the semiconductor device, the gate electrode facing the active layer with the charge storage layer interposed therebetween; and
injecting charges present in the active layer into the charge storage layer based on the gate voltage.

20. The method of claim 18, wherein the detecting of the image comprises:
forming, by the photo-sensitive layer, electron-hole pairs based on an external optical signal; and
moving electrons included in the electron-hole pairs from the photo-sensitive layer to the active layer,
wherein a magnitude of the analog signal is determined based on a conductivity of the active layer that depends on the weight data.
